(19) United States
(12) Patent Application Publication
(10) Pub. No.: US 2004/0264132 A1
(43) Pub. Date: Dec. 30, 2004

(54) Method for forming storage node contact plug of semiconductor device

(76) Inventors: Yu-Chang Kim, Ichon-shi (KR); Yun-Seok Cho, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/746,108

(22) Filed: Dec. 23, 2003

(30) Foreign Application Priority Data
Jun. 30, 2003 (KR) 2003-43070

(51) Int. Cl. H05K 7/20

(52) U.S. Cl. 361/695

(57) ABSTRACT

The present invention relates to a method for forming a storage node contact plug of a semiconductor device. The method includes the steps of: forming a bit line structure including a bit line and a hard mask on a substrate; forming a spacer made of an oxide material at sidewalls of the bit line structure; forming a line type photoresist pattern arranged in a direction vertical to the bit line structure on a storage node contact area of the substrate; forming an inter-layer insulation layer on an entire surface of the resulting structure including the line type photoresist pattern such that the inter-layer insulation layer is filled into a space between the photoresist pattern; etching an upper portion of the inter-layer insulation layer to expose the photoresist pattern; and removing the exposed photoresist pattern to open the storage node contact area.

### FIELD OF THE INVENTION

The present invention relates to a method for forming a storage node contact plug of a semiconductor device; and, more particularly, to a method for forming a storage node contact plug of a semiconductor device by employing a line type contact process.

### DESCRIPTION OF RELATED ARTS

Generally, a contact process in a semiconductor device is classified into a hole type and a line type. The hole type contact process is advantageous in achieving a more simplified process. Currently, despite that the line type contact process is more complicated than the hole type contact process, the line type is more frequently adopted with consideration of a margin by a design rule changing corresponding to a trend of large-scale of integration. That is, the line type contact process is much advantageous in securing a contact area even if a misalignment occurs.

However, in the course of forming the storage node contact plug with use of the line type contact process, a bit line hard mask is damaged severely when an inter-layer insulation layer for opening a storage node contact area is etched. Thus, the thickness of the bit line hard mask is increased to solve the above problem. However, this increased thickness results in an increase of an aspect ratio, which becomes a factor for deteriorating a gap-fill property. Also, it becomes difficult to secure an intended area of the contact area and a desired selectivity ratio with respect to a photoresist pattern during the etching for forming the bit line hard mask. Also, as large-scale of integration have been gradually led to fine patterns, a spacing distance between the bit lines have been gradually decreased. This decreased spacing distance pronounces the loss of the bit line hard mask in more extents, necessitating an increase in the thickness of the bit line hard mask. As a result, the above mentioned problems become more severe, further degrading characteristics and reliability of devices.

### SUMMARY OF THE INVENTION

It is, therefore, an object of the present invention to provide a method for forming a storage node contact plug of a semiconductor device capable of improving device characteristics and reliability by opening a storage node contact area without inducing losses of a bit line hard mask during a line type contact process.

In accordance with an aspect of the present invention, there is provided a method for forming a storage node contact plug of a semiconductor device, including the steps of: forming a bit line structure including a bit line and a hard mask on a substrate; forming a spacer made of an oxide material at sidewalls of the bit line structure; forming a line type photoresist pattern arranged in a direction vertical to the bit line structure on a storage node contact area of the substrate; forming an inter-layer insulation layer on an entire surface of the resulting structure including the line type photoresist pattern such that the inter-layer insulation layer is filled into a space between the photoresist pattern; etching an upper portion of the inter-layer insulation layer to expose the photoresist pattern; and removing the exposed photoresist pattern to open the storage node contact area.

### BRIEF DESCRIPTION OF THE DRAWING(S)

The above and other objects and features of the present invention will become apparent from the following description of the preferred embodiments given in conjunction with the accompanying drawings, in which:

FIGS. 1A to 1F are cross-sectional views illustrating a method for forming a storage node contact plug of a semiconductor device in accordance with a preferred embodiment of the present invention; and

FIG. 2 is a perspective view of the storage node contact plug of the semiconductor device viewed in a direction of the line X-x′ in accordance with the preferred embodiment of the present invention.

### DETAILED DESCRIPTION OF THE INVENTION

Hereinafter, a preferred embodiment of the present invention will be described in detail with reference to the accompanying drawings.

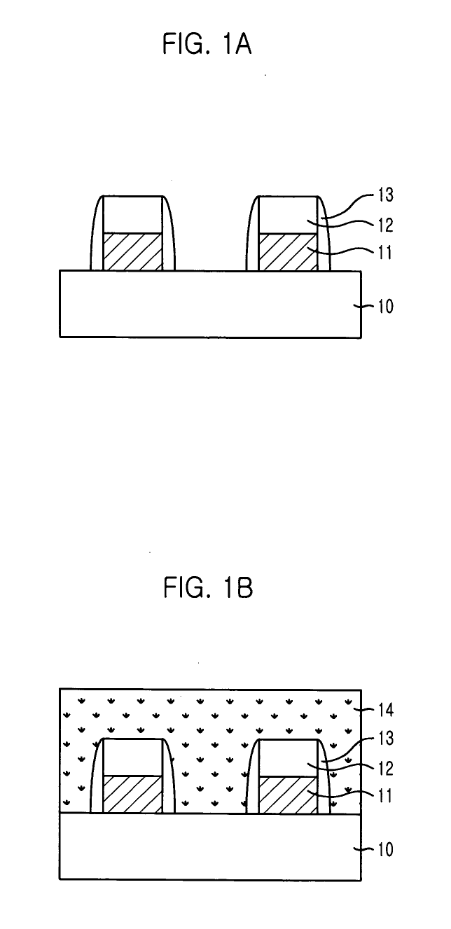

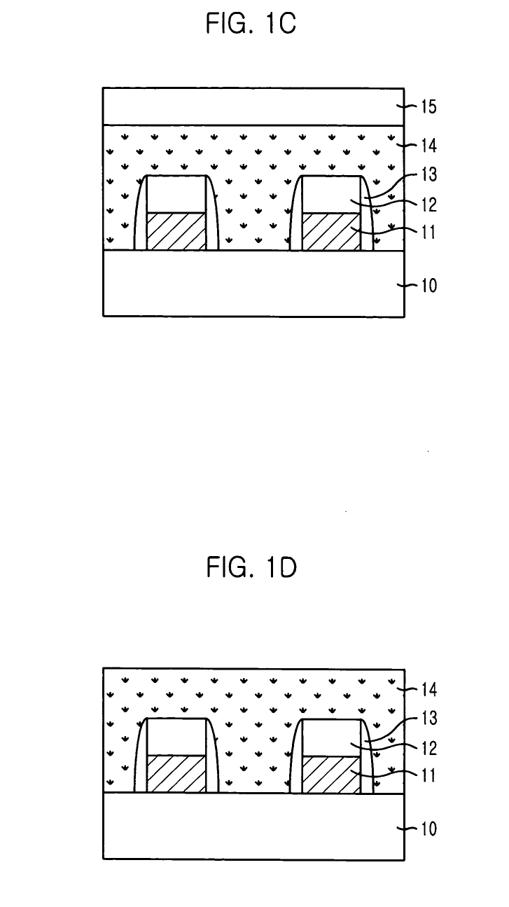

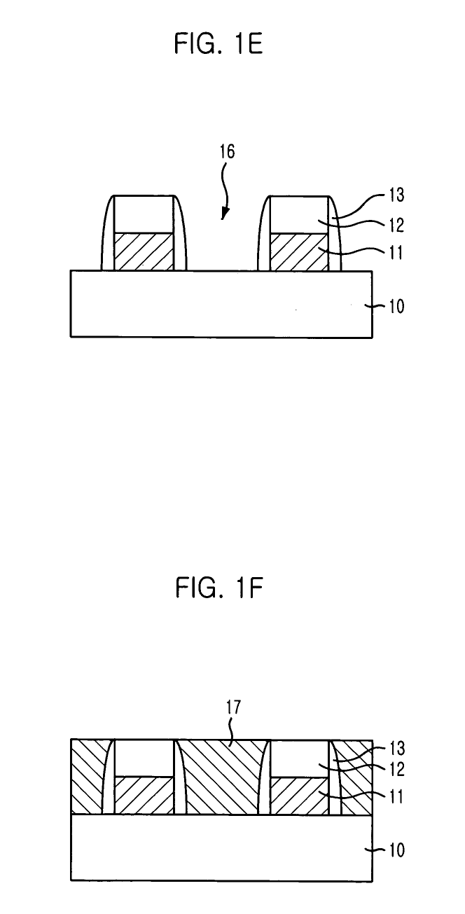

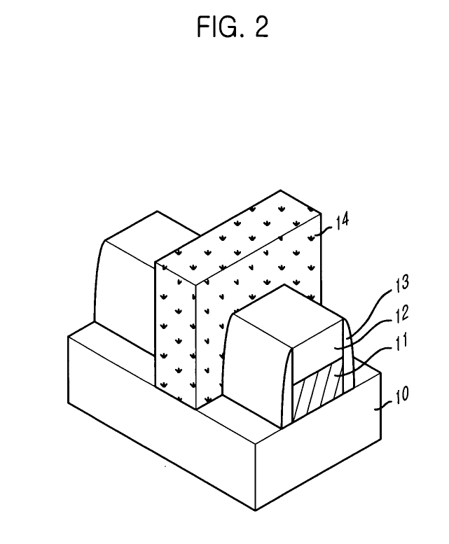

FIGS. 1A to 1F are cross-sectional views illustrating a method for forming a line type storage node contact plug of a semiconductor device in accordance with a preferred embodiment of the present invention. FIG. 2 is a perspective view of the storage node contact plug shown in FIG. 1B.

Referring to FIG. 1A, a plurality of bit line structures each including a bit line 11 and a hard mask 12 made of nitride is formed on a substrate 10. Although it is not illustrated, each bit line 11 is connected to the substrate 10 through individual landing plugs each isolated by an insulation layer. Preferably, the bit line 11 includes a stack structure of a tungsten (W) layer, a titanium nitride (TiN) layer and a titanium (Ti) layer or a stack structure of a tungsten silicide (WSi), a titanium nitride (TiN) and a titanium (Ti) layer. Compared to a conventionally formed hard mask having a thickness ranging from about 2000 Å to about 2500 Å, the hard mask 12 has a thin thickness ranging from about 1000 Å to about 1500 Å. Then, an oxide layer is deposited on an entire surface of the above resulting structure including the bit line structures and is then etched in a manner that a surface of the substrate 10 is exposed. From this etching of the oxide layer, a spacer 13 made of an oxide material is formed at sidewalls of each bit line structure. Preferably, the oxide layer is made of plasma enhanced tetra-ethyl-ortho-silicate (PE-TEOS) in order to reduce a parasitic capacitance. Also, the etching of the oxide layer proceeds by employing a plasma using a gaseous chemical of carbon tetrafluoride (CF₄), trifluoromethane (CHF₃), oxygen (O₂) and argon (Ar).

Referring to FIG. 1B and FIG. 2, a photoresist is coated on an entire surface of the above structure such that the photoresist is filled into a space between the bit line structures. A line type photoresist pattern 14 is formed by performing a photo-exposure process and a developing process with use of a storage node contact mask. Herein, the line type photoresist pattern 14 is arranged in a direction vertical to the bit line structure. Afterwards, the photoresist pattern 14 is hardened by performing a hard bake process and an ultra violet (UV) bake process. Also, formation of an organic-material based anti-reflective coating (ARC) layer at bottom of the photoresist pattern 14 can be possibly omitted. Also, the photoresist pattern 14 is formed with the photoresist for use in a light source of KrF, which is employed for the photo-exposure process.

Referring to FIG. 1C, an inter-layer insulation layer 15 is deposited on an entire surface of the resulting structure including the photoresist pattern 14 in a manner that the inter-layer insulation layer 15 is filled into a space between the photoresist patterns 14. Herein, a problem related to a gap-fill property does not arise since portions of the inter-layer insulation layer 15 buried into the space between the photoresist patterns 14 are not etched during a subsequent etching process. Thus, the inter-layer insulation layer 15 can be made of a material having a poor gap-fill property such as high density plasma (HDP). However, under consideration of losses of the photoresist pattern 14 at a high temperature, the deposition of the inter-layer insulation layer 15 proceeds at a low temperature of below about 200° C.

Referring to FIG. 1D, a chemical mechanical polishing (CMP) process is performed to etch an upper portion of the inter-layer insulation layer 15 to expose the photoresist pattern 14.

Referring to FIG. 1E, a storage node contact area 16 on the substrate 10 is opened by removing the exposed photoresist pattern 14. Preferably, a dry stripping process using oxygen (O₂) plasma is performed to remove the photoresist pattern 14. At this time, if carbon tetrafluoride (CF₄) gas is added to the O₂ plasma with a small quantity below about 10% of the total O₂ plasma composition ratio, it is possible to easily remove the photoresist pattern 14 with regardless of a degree of hardness and to achieve an effect of cleaning a surface of the photoresist pattern 14. Herein, the storage node contact area 16 is a landing plug.

Referring to FIG. 1F, a conductive layer such as a metal layer made of titanium nitride (TiN) or polysilicon is deposited on the inter-layer insulation layer 15 to bury the opened contact area 16. Then, the conductive layer and the inter-layer insulation layer 15 are etched by performing a CMP process to make a surface of the hard mask 13 be exposed. From this CMP process, the conductive layer is isolated to form a plurality of storage node contact plugs 17. At this time, a thickness of the removed portion of the hard mask 13 ranges from about 300 Å to about 400 Å.

Based on the preferred embodiment of the present invention, it is possible to prevent losses of the bit line hard mask usually occurring during formation of the contact area through a specific series of processes. The photoresist pattern is first formed on the storage node contact area disposed between the bit lines. The inter-layer insulation layer is deposited thereon, and the photoresist pattern is removed thereafter to open the storage node contact area. As a result, the thickness of the bit line hard mask is not needed to be increased, and thereby preventing an increase in an aspect ratio and easily securing a desired selectivity ratio and an intended area of the contact area. These effects further make it possible to improve device characteristics and reliability.

While the present invention has been described with respect to certain preferred embodiments, it will be apparent to those skilled in the art that various changes and modifications may be made without departing from the scope of the invention as defined in the following claims.

What is claimed is:

1. A method for forming a storage node contact plug of a semiconductor device, comprising the steps of:
forming a bit line structure including a bit line and a hard mask on a substrate;
forming a spacer made of an oxide material at sidewalls of the bit line structure;
forming a line type photoresist pattern arranged in a direction vertical to the bit line structure on a storage node contact area of the substrate;
forming an inter-layer insulation layer on an entire surface of the resulting structure including the line type photoresist pattern such that the inter-layer insulation layer is filled into a space between the photoresist pattern;
etching an upper portion of the inter-layer insulation layer to expose the photoresist pattern; and
removing the exposed photoresist pattern to open the storage node contact area.

2. The method as recited in claim 1, wherein a hard bake process and an ultra violet (UV) bake process are performed after the formation of the photoresist pattern but prior to the formation of the inter-layer insulation layer in order to harden the photoresist pattern.

3. The method as recited in claim 1, wherein the line type photoresist pattern is formed by using a photoresist for use in a light source of KrF.

4. The method as recited in claim 2, wherein the line type photoresist pattern is removed by performing a dry stripping process using oxygen (O₂) plasma.

5. The method as recited in claim 3, wherein the line type photoresist pattern is removed by performing a dry stripping process using oxygen (O₂) plasma.

6. The method as recited in claim 4, wherein the line type photoresist pattern is removed by using carbon tetrafluoride (CF4) gas added with a quantity less than about 10% of the total O₂ plasma composition ratio.

7. The method as recited in claim 5, wherein the line type photoresist pattern is removed by using carbon tetrafluoride (CF4) gas added with a quantity less than about 10% of the total O₂ plasma composition ratio.

8. The method as recited in claim 1, wherein the inter-layer insulation layer is deposited at a low temperature of below about 200° C.

9. The method as recited in claim 1, wherein the oxide material used in forming the spacer is plasma enhanced tetra-ethyl-ortho-silicate (PE-TEOS).

10. The method as recited in claim 1, further comprising the steps of:
depositing a conductive layer on the inter-layer insulation layer such that the conductive layer buries the storage node contact area; and
isolating the conductive layer by etching the conductive layer and the inter-layer insulation layer until the hard mask is exposed.

11. The method as recited in claim 1, wherein the hard mask has a thickness ranging from about 1000 Å to about 1500 Å.

12. The method as recited in claim 10, wherein the hard mask has a thickness ranging from about 1000 Å to about 1500 Å.

13. The method as recited in claim 10, wherein at the step of isolating the conductive layer, a thickness of the removed hard mask ranges from about 300 Å to about 400 Å.
